(19) United States
(12) Patent Application Publication
(10) Pub. No.: US 2026/0093887 A1
(43) Pub. Date: Apr. 2, 2026

(54) FOLDED REGISTER FILE

(71) Applicant: Advanced Micro Devices, Inc., Santa Clara, CA (US)

(72) Inventors: Eric Dixon, Fort Collins, CO (US); Christopher S. Oliver, Austin, TX (US); Naveensurya Kalaivannan, Austin, TX (US); Erik Swanson, Fort Collins, CO (US)

(73) Assignee: Advanced Micro Devices, Inc., Santa Clara, CA (US)

(21) Appl. No.: 18/901,498

(22) Filed: Sep. 30, 2024

(51) Int. Cl. G06F 30/337

(52) U.S. Cl. CPC G06F 30/337

(57) ABSTRACT

The disclosed device includes a physical register file (PRF) in a stacked die configuration. Part of the PRF can be implemented in a first die, and another part of the PRF can be implemented in a second die stacked over the first die. The stacked dies can have a similar layout to allow a simplified addressing scheme for accessing the dies of the PRF. Various other methods, systems, and computer-readable media are also disclosed.

### BACKGROUND

A processor can include multiple functional units, such as arithmetic logic units (ALUs) and other processing/logic circuits for performing math/logic operations on data values. Although the data values are read from a memory, rather than directly sending the read data values to the functional units, the processor can stage the data values in a local storage such as a register. The processor can have a register file corresponding to an array of registers for use with the functional units. A physical register file (PRF) corresponds to a physical (die) structure of the processor's register file. The functional units can access physical locations in the PRF through a controller. However, processor performance, such as instructions per cycle (IPC), efficient utilization of functional units, etc., can be affected by the PRF and/or architecture thereof.

### BRIEF DESCRIPTION OF THE DRAWINGS

The accompanying drawings illustrate a number of exemplary implementations and are a part of the specification. Together with the following description, these drawings demonstrate and explain various principles of the present disclosure.

FIG. 1 is a block diagram of an example system for a folded register file.

FIG. 2 is a block diagram of an example data path for a register file.

FIG. 3 is a block diagram of an example stacked die configuration for a register file.

FIG. 4 is a block diagram of an example stacked configuration for a register file.

FIG. 5A-C are block diagrams of example configurations and addressing schemes for a folded register file.

FIG. 6 is a flow diagram of an example method for accessing a folded register file.

Throughout the drawings, identical reference characters and descriptions indicate similar, but not necessarily identical, elements. While the exemplary implementations described herein are susceptible to various modifications and alternative forms, specific implementations have been shown by way of example in the drawings and will be described in detail herein. However, the exemplary implementations described herein are not intended to be limited to the particular forms disclosed. Rather, the present disclosure covers all modifications, equivalents, and alternatives falling within the scope of the appended claims.

### DETAILED DESCRIPTION

The present disclosure is generally directed to a folded register file. As will be explained in greater detail below, implementations of the present disclosure include a physical register file (PRF) having a first die layer and a second die layer stacked over the first die layer. A control circuit manages access to the dies of the PRF using an addressing scheme. The systems and methods described herein provide a PRF having an efficient structure (e.g., higher capacity storage for a given footprint/area) without requiring a complicated addressing scheme (e.g., without significant increases to a number of cycles for accessing the PRF) to allow improved processor performance.

Features from any of the implementations described herein can be used in combination with one another in accordance with the general principles described herein. These and other implementations, features, and advantages will be more fully understood upon reading the following detailed description in conjunction with the accompanying drawings and claims.

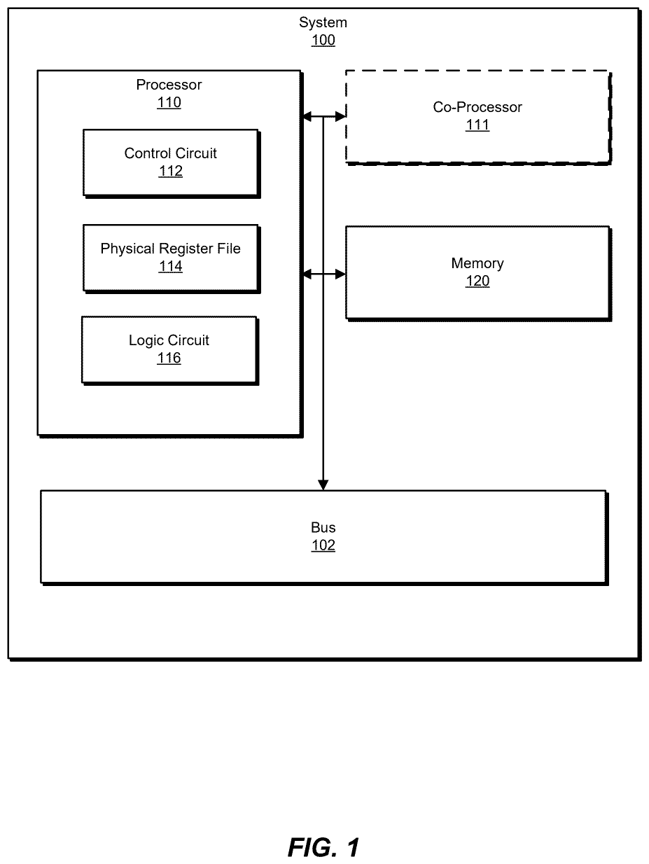

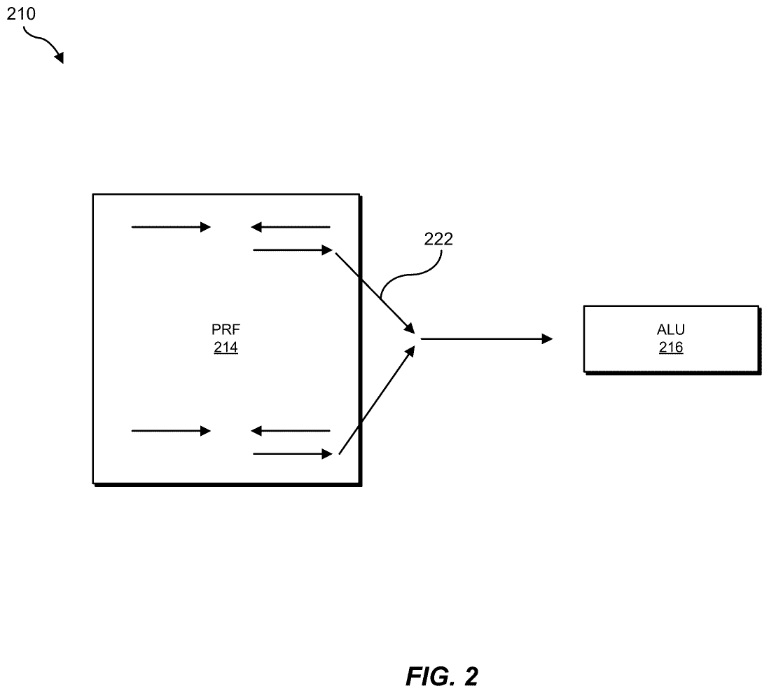

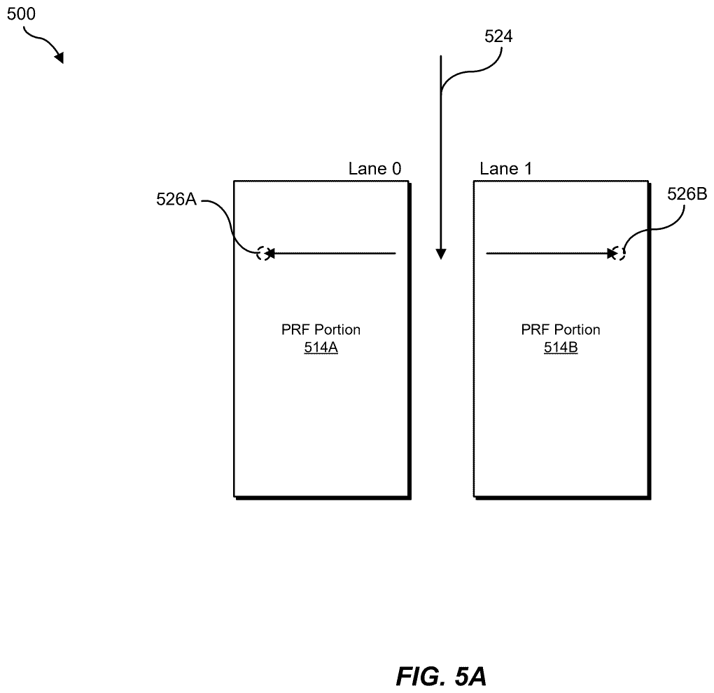

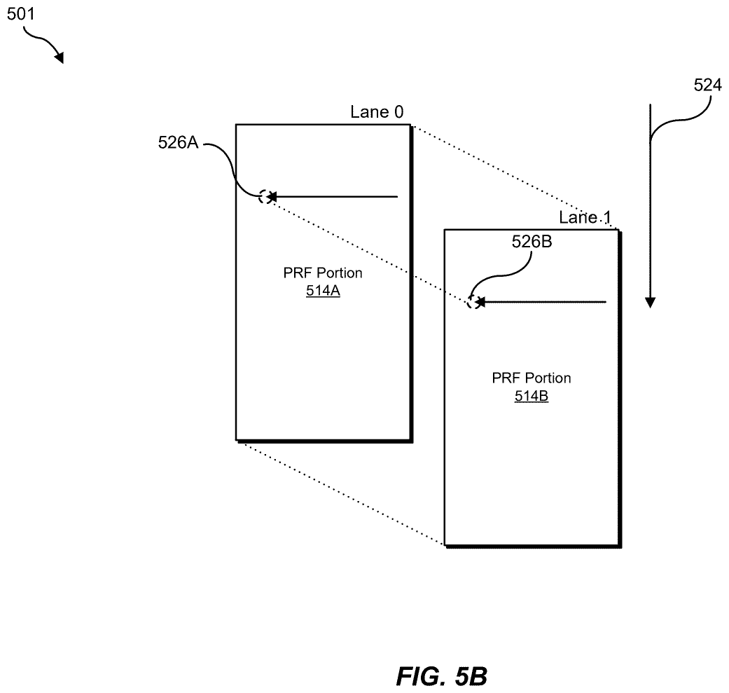

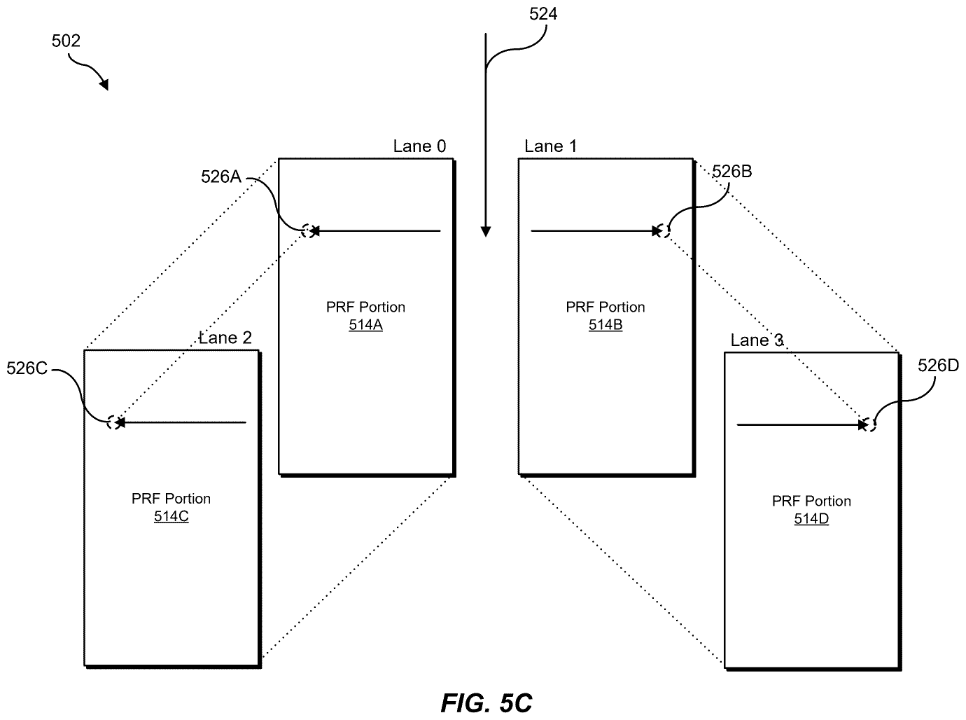

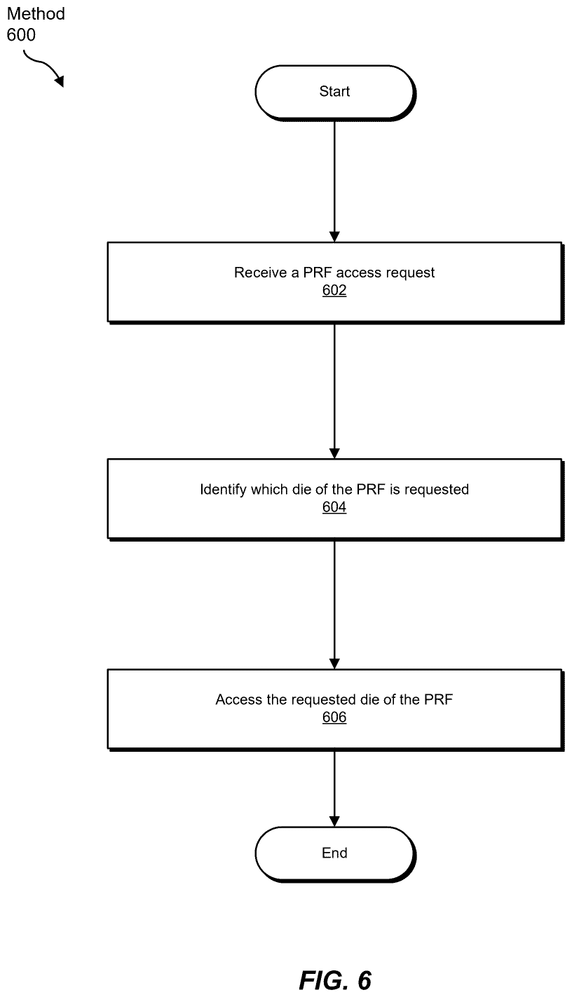

The following will provide, with reference to FIGS. 1-6, detailed descriptions of a folded register file (e.g., a stacked PRF). Detailed descriptions of example systems and devices will be provided in connection with FIG. 1. Detailed descriptions of example data paths for PRFs will be provided in connection with FIGS. 2-4. Detailed descriptions of example addressing schemes will be provided in connection with FIG. 5A-5C. In addition, detailed descriptions of corresponding methods will also be provided in connection with FIG. 6.

FIG. 1 is a block diagram of an example system 100 for a folded register file. System 100 corresponds to a computing device, such as a desktop computer, a laptop computer, a server, a tablet device, a mobile device, a smartphone, a wearable device, an augmented reality device, a virtual reality device, a network device, and/or an electronic device. As illustrated in FIG. 1, system 100 includes one or more memory devices, such as memory 120. Memory 120 generally represents any type or form of volatile or non-volatile storage device or medium capable of storing data and/or computer-readable instructions. Examples of memory 120 include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, and/or any other suitable storage memory.

As illustrated in FIG. 1, example system 100 includes one or more physical processors, such as processor 110, which can correspond to one or more processors (e.g., a host processor along with a co-processor, which in some examples can be separate processors). Processor 110 generally represents any type or form of hardware-implemented processing unit capable of interpreting and/or executing computer-readable instructions. In some examples, processor 110 accesses and/or modifies data and/or instructions stored in memory 120. Examples of processor 110 include, without limitation, one or more instances of chiplets (e.g., smaller and in some examples more specialized processing units that can coordinate as a single chip), microprocessors, microcontrollers, Central Processing Units (CPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, accelerated processing units (APUs), neural processing units (NPUs), tensor processing units (TPUs), other highly parallel processor units (PPUs), portions of one or more of the same, variations or combinations of one or more of the same (e.g., a host processor and a co-processor), and/or any other suitable physical processor(s). Further, in some examples, processor 110 can be a general-purpose processor that can be capable, without significant limitation, of various computing tasks, as opposed to a special purpose processor that can be limited in computing tasks (e.g., specially designed for particular computing tasks such as moving data, performing certain mathematical operations, etc.), although in other examples processor 110 can correspond to and/or incorporate one or more special purpose processors.

As also illustrated in FIG. 1, example system 100 can in some implementations optionally include one or more physical co-processors, such as co-processor 111, which in other implementations can be integrated with or otherwise represented by processor 110. Co-processor 111 generally represents any type or form of hardware-implemented processing unit capable of interpreting and/or executing computer-readable instructions, which in some examples works in conjunction and/or based on instructions from a host/main processor such as a CPU (e.g., processor 110). In some examples, co-processor 111 accesses and/or modifies data and/or instructions stored in memory 120. Examples of co-processor 111 include, without limitation, chiplets (e.g., smaller and in some examples more specialized processing units that can coordinate as a single chip), microprocessors, microcontrollers, graphics processing units (GPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, accelerated processing units (APUs), neural processing units (NPUs), tensor processing units (TPUs), other highly parallel processor units (PPUs), portions of one or more of the same, variations or combinations of one or more of the same, and/or any other suitable physical processor.

FIG. 1 also includes a bus 102 that can correspond to any bus, circuitry, connections, and/or any other communicative pathways for sending communicative signals, based on one or more communication protocols, between components/devices (e.g., processor 110, memory 120, and/or co-processor 111, etc.). In some implementations, bus 102 can further connect, via wireless and/or wired connections, to other devices, such as peripheral devices external to or partially integrated with system 100. Although not illustrated in FIG. 1, in some implementations, system 100 can be coupled to a display device (e.g., via bus 102).

As further illustrated in FIG. 1, processor 110 includes a control circuit 112, a physical register file (PRF) 114, and a logic circuit 116. Control circuit 112 corresponds to an access controller for PRF 114 and includes one or more circuits/circuitry and/or instructions for implementing an addressing scheme to access physical locations of PRF 114 for reading/storing data values, as will be described further below. PRF 114 corresponds to a physical structure for a local storage of processor 110 (e.g., a register array) and can include a stacked die configuration, as will be described further below. Logic circuit 116 corresponds to one or more circuits/circuitry for performing processing operations (e.g., arithmetic/logic operations), such as an ALU, floating point (FP) unit, and/or any other functional unit.

In some examples, logic circuit 116 performs operations on data values held in PRF 114. Processor 110 can read data values from memory 120 into PRF 114. An instruction or operation can include an address (e.g., corresponding to a register) as an operand. Control circuit 112 can manage a corresponding access request (e.g., for reading from and/or writing to a register) for PRF 114 by accessing a physical location in PRF 114 corresponding to the address/register in the access request. A result of the operation can be stored in the same/different register (e.g., via another access request to PRF 114), to be written to memory 120 as needed.

Increasing a size of PRF 114 can improve certain aspects of a performance of processor 110. For instance, holding more values in PRF 114 can reduce a number of expensive (e.g., high overhead) accesses to memory 120, and further can allow multiple functional units (e.g., additional iterations of logic circuit 116, not illustrated in FIG. 1) to operate. Certain other processor functions such as context switching (e.g., switching from one thread of executing instructions to a different thread of executing instructions by saving a current processor state) can also benefit from a larger PRF.

However, increasing PRF 114 can introduce other challenges. FIG. 2 illustrates portions of a processor 210 corresponding to processor 110. FIG. 2 illustrates a PRF 214 (corresponding to PRF 114), an arithmetic logic unit (ALU) 216 (corresponding to logic circuit 116) and a data path 222 therebetween. FIG. 2 illustrates a simplified diagram for explanatory purposes.

Data path 222 represents a signal path (e.g., physical connections such as nodes/electrodes, wires/traces, etc.) for data from one physical location (e.g., PRF 214) to another physical location (e.g., ALU 216). As illustrated in FIG. 2, a path distance (e.g., corresponding to a number and/or type of physical connections traversed by a signal and corresponding to an estimate of a physical distance of such connections) of data path 222 can depend on which particular location in PRF 214 is accessed. Assuming, for explanatory purposes, that a right side of PRF 214 is near an interface/bus connected to ALU 216, the path distance for registers physically located on the right side of PRF 214 can be shorter than the path distance for registers physically located on the left side of PRF 214. In other words, a worst-case path distance can correspond to a side of PRF 214 farthest from ALU 216. In addition, although not illustrated in FIG. 2, processor 210 can include additional functional units located further from PRF 214 that can also increase the worst-case path distance.

Increasing a size of PRF 214, without rearranging ALU 216 (e.g., moving closer to PRF 214) can cause the farthest side to move further away. Accordingly, as rearranging ALU 216 can be unfeasible (e.g., due to other components, manufacturing/fabrication limitations, etc.), increasing the size of PRF 214 can increase the worst-case path distance, unfavorably adding latency.

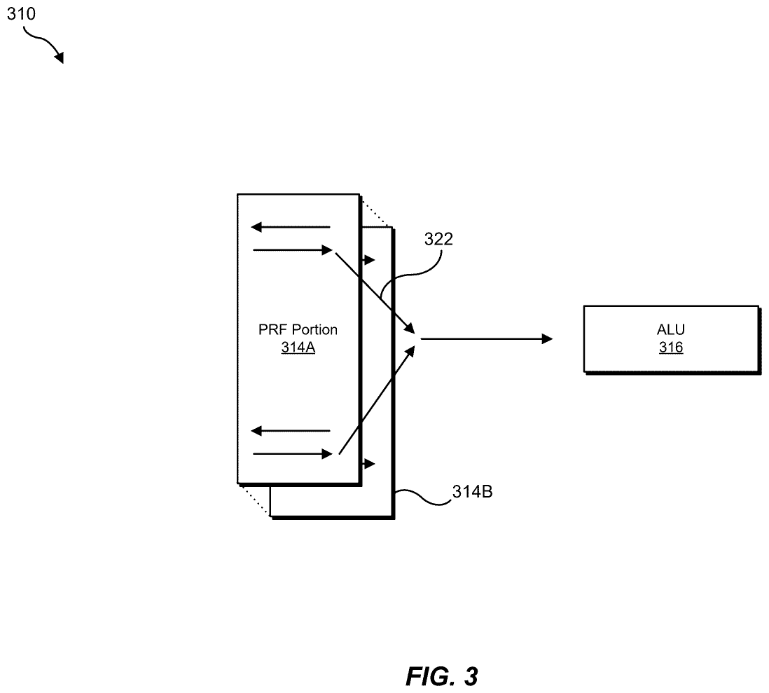

FIG. 3 illustrates portions of a processor 310 corresponding to processor 110. FIG. 3 illustrates a PRF portion 314A and a PRF portion 314B (collectively corresponding to PRF 114), an arithmetic logic unit (ALU) 316 (corresponding to logic circuit 116) and a data path 322 therebetween. FIG. 3 illustrates a simplified diagram for explanatory purposes.

In FIG. 3, PRF portion 314A can correspond to a die and PRF portion 314B can correspond to another die. PRF portion 314A and PRF portion 314B can be in separate die layers such that PRF portion 314A is at least partially stacked over PRF portion 314B. This stacked die configuration of the PRF allows the PRF to conceptually be folded over itself (e.g., a folded register file). In some examples, PRF portion 314A can be aligned over PRF portion 314B, as will be described further below, although in other examples PRF portion 314A can partially overlap PRF portion 314B. PRF portion 314A and PRF portion 314B collectively represent a stacked die configuration for a PRF.

As illustrated in FIG. 3, a structure of PRF portion 314A can match a structure of PRF portion 314B (e.g., by having one or more similar and/or ostensibly same dimensions and/or including a similar and/or ostensibly same number of physical registers in a similar and/or ostensibly same pattern or arrangement). Accordingly, a worst-case path distance for data path 322 can be similar and/or ostensibly same for PRF portion 314A and PRF portion 314B. If the PRF has a similar capacity to that of PRF 214 in FIG. 2 (e.g., PRF portion 314A and PRF portion 314B each corresponding to half of the capacity of PRF 214), the stacked die arrangement in FIG. 3 can provide a significant improvement to the worst-case path distance with similar capacity. Alternatively, the PRF of FIG. 3 can have a greater capacity than that of PRF 214 without a significantly increased worst-case path distance. For example, if each of PRF portion 314A and PRF portion 314B has a similar size/capacity to that of PRF 214 (e.g., effectively doubling PRF 214), the worst-case path distance is not significantly worse than that of PRF 214.

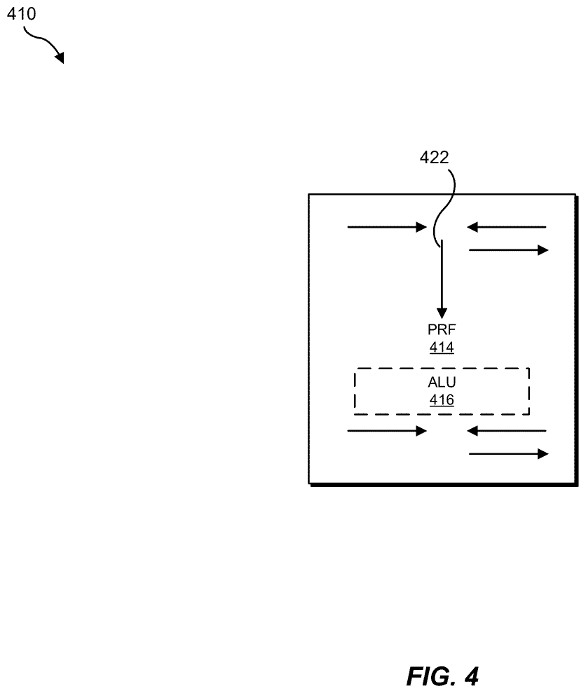

FIG. 4 illustrates portions of a processor 410 corresponding to processor 110. FIG. 4 illustrates a PRF 414 (corresponding to PRF 114), an arithmetic logic unit (ALU) 416 (corresponding to logic circuit 116) and a data path 422 therebetween. FIG. 4 illustrates a simplified diagram for explanatory purposes.

FIG. 4 illustrates an alternative stacked arrangement having PRF 414 stacked over ALU 416. As the physical proximity of ALU 416 and PRF 414 can reduce path distances, PRF 414 can be larger (with respect to PRF 214) without significantly increasing a worst-case path distance (with respect to PRF 214).

Although increased capacity and/or more efficient layout provided by a folded register file (as illustrated in FIG. 3) can be advantageous, a control circuit (e.g., control circuit 112) can implement an updated addressing scheme to access the dies of the PRF. However, a complicated addressing scheme can require a larger control circuit and/or otherwise increase access latency, which can reduce potential performance benefits from the folded register file.

In some implementations, the structure/layout of the PRF dies can allow a simplified addressing scheme. For instance, symmetry amongst the dies can allow identifying dies with a single value (e.g., a lane value as will be described further below) that can be appended to an address value. This symmetry of different dies (e.g., different lane values), as will be described further below, also allows symmetry with respect to path distances. FIG. 5A illustrates an arrangement 500 having a PRF portion 514A and a PRF portion 514B (collectively corresponding to PRF 114 and in some examples, corresponding respectively to PRF portion 314A and PRF portion 314B). In FIG. 5A, PRF portion 514A can be lateral to PRF portion 514B (e.g., residing in the same die layer).

In FIG. 5A, a structure of PRF portion 514A can mirror a structure of PRF portion 514B such that an arrangement of physical registers can correspond to a reflection about an axis (e.g., a center between PRF portion 514A and PRF portion 514B in FIG. 5A, which can further correspond to an interface). A corresponding addressing scheme can be based on higher address values representing physical locations further away from the interface, such as if the physical registers are arranged in a grid, for a given row higher address values can represent locations further away from the interface.

An access request 524 can include an address value and a lane value, which in some implementations can be appended to (e.g., before or after) the address value. For access request 524, the address value can correspond to a physical location 526A (e.g., a particular physical register of PRF portion 514A) and also to a physical location 526B (e.g., a particular physical register of PRF portion 514B). As illustrated in FIG. 5A, due to the symmetry, physical location 526A can mirror physical location 526B (e.g., being generally equidistant from the interface along a generally same row).

The lane value can identify which of PRF portion 514A and PRF portion 514B to access. For instance, having two lanes (e.g., corresponding to the two portions), the lanes can be identified as lane 0 or lane 1. Further, a bit width of the lane value can correspond to a number of lanes/dies. In FIG. 5A, a single bit can be used for the lane value, to allow only a 1-bit increase in the addressing scheme for addresses.

FIG. 5B illustrates another arrangement 501 in which PRF portion 514A can be stacked over PRF portion 514B. The structure of PRF portion 514A can match the structure of PRF portion 514B such that the grid arrangement of physical registers is generally vertically aligned (e.g., mirror about a plane between the dies). For example, physical location 526A can be generally vertically aligned with physical location 526B for the same address value.

FIG. 5C illustrates yet another arrangement 502 that further includes a PRF portion 514C and a PRF portion 514D (each corresponding to additional dies of a PRF such as PRF 114). PRF portion 514C can be stacked over (and have matching structures with) PRF portion 514A. PRF portion 514D can be stacked over (and have matching structures with) PRF portion 514B. PRF portion 514A can be lateral to PRF portion 514B, and PRF portion 514C can be lateral to PRF portion 514D. Further, PRF portion 514A can mirror PRF portion 514B. Similarly, PRF portion 514D can mirror PRF portion 514D.

With four symmetrical dies, the address value of access request 524 can correspond to physical location 526A, physical location 526B, a physical location 526C, and a physical location 526D. As illustrated in FIG. 5C physical location 526A can mirror physical location 526B (e.g., with respect to the interface) and similarly physical location 526C can mirror physical location 526D. Further, physical location 526C can be generally aligned vertically over physical location 526A, and physical location 526D can be generally aligned vertically over physical location 526B.

With four dies, the lane value can include 2 bits (e.g., for lane 0, lane 1, lane 2, and lane 3, as illustrated in FIG. 5C), such that the bit width needed for the lane value can correspond to a number of dies/lanes. The addressing scheme allows identification between dies without significant overhead (e.g., as would be needed for an addressing scheme encompassing all physical locations of the four dies) and further can mitigate a bit width needed to represent physical locations.

Moreover, although FIGS. 5A-5C illustrate simplified examples of folded register files, in other examples the folded register file can include additional dies (e.g., additional stacks of dies) and additional dies in each stack (e.g., more than two die layers). Further, although FIGS. 5A-5C illustrate generally symmetrical arrangements, in other examples, other arrangements such as asymmetrical, partially symmetric and/or partially asymmetric, and combinations thereof, can be used.

FIG. 6 is a flow diagram of an exemplary computer-implemented method 600 for accessing a folded register file. The steps shown in FIG. 6 can be performed by any suitable computer-executable code and/or computing system, including the system(s) illustrated in FIGS. 1, 3, and/or 5A-5C. In one example, each of the steps shown in FIG. 6 represent an algorithm whose structure includes and/or is represented by multiple sub-steps, examples of which will be provided in greater detail below.

As illustrated in FIG. 6, at step 602 one or more of the systems described herein receive a PRF access request. For example, control circuit 112 can receive an access request (e.g., access request 524) for a PRF (e.g., PRF 114). In some examples, the access request can follow an addressing scheme including an address value (corresponding to a physical location on a die of the PRF) and a lane value (corresponding to a particular die). For instance, PRF 114 can include one or more stacks of dies, each die being identified with a unique lane value.

At step 604 one or more of the systems described herein identify which dies of the PRF is requested. For example, control circuit 112 can identify, using the lane value, the particular die or otherwise differentiate between the multiple dies with the lane value. In FIG. 5C, control circuit 112 can identify which die (e.g., PRF portion 514A, PRF portion 514B, PRF portion 514C, or PRF portion 514D) based on the lane value (e.g., lane 0, lane 1, lane 2,or lane 3, respectively).

At step 606 one or more of the systems described herein access the requested die of the PRF. For example, control circuit 112 can access the physical location represented by the address value of the appropriate die to read or write a value.

In addition, although the examples described above reference a single value, in some examples, the access request can correspond to a vector value or otherwise wider values (e.g., multiple registers). For example, the address value can represent the first register of a group of registers, such as a first register for a vector, a first register for a value wider than a single register (e.g., doubleword, quadword, etc.).

As detailed above, the systems and methods described herein provide a folded register file having more efficient storage without adding significant latency. For instance, using the addressing scheme described herein, the access times are not significantly increased compared to a planar register file of similar capacity such that a number of cycles (and accordingly an operating frequency) is not negatively impacted. More specifically, PRF capacity can be effectively doubled without significant added latency. Alternatively, a higher frequency can be achieved by keeping the same capacity PRF split into two or more dies. A smaller footprint associated with stacking dies can provide additional benefits (e.g., improved latency due to shorter data paths).

In yet further implementations, certain dies of the PRF can be reserved for certain functional units, allowing increased parallel processing. For example, a first die (e.g., PRF portion 314A in FIG. 3) can be reserved for first functional unit (e.g., ALU 316), and a second die (e.g., PRF portion 314B) can be reserved for a different functional unit (e.g., a different iteration of logic circuit 116). In such implementations, the lane value can also be indicative of the corresponding functional unit.

In some aspects, the techniques described herein relate to a device including: a physical register file (PRF) including: a first portion in a first die layer; and a second portion in a second die layer and at least partially stacked over the first portion; and a control circuit configured to manage access from a logic circuit to the first portion and the second portion.

In some aspects, the techniques described herein relate to a device, wherein a first path distance of a first data path between the logic circuit and the first portion is ostensibly same as a second path distance of a second data path between the logic circuit and the second portion.

In some aspects, the techniques described herein relate to a device, wherein a first structure of the first portion matches a second structure of the second portion.

In some aspects, the techniques described herein relate to a device, wherein the control circuit is configured to manage access to the first portion and the second portion with an addressing scheme that uses a lane value to differentiate between the first portion and the second portion.

In some aspects, the techniques described herein relate to a device, wherein: a first physical location of the first portion has a first address and a first lane value; a second physical location of the second portion has a second address and a second lane value; and the second address is similar to the first address and the second lane value is different from the first lane value such that the second physical location is generally vertically aligned with the first physical location.

In some aspects, the techniques described herein relate to a device, wherein the first path distance for the first physical location is ostensibly the same as the second path distance for the second physical location.

In some aspects, the techniques described herein relate to a device, wherein the addressing scheme uses a lane value including 1 bit.

In some aspects, the techniques described herein relate to a device, wherein: the PRF further includes: a third portion lateral to the first portion in the first die layer; and a fourth portion lateral to the second portion in the second die layer and at least partially stacked over the third portion; and the control circuit is further configured to manage access from the logic circuit to the first portion, the second portion, the third portion and the fourth portion with an addressing scheme that uses a lane value to differentiate between the first portion, the second portion, the third portion and the fourth portion.

In some aspects, the techniques described herein relate to a device, wherein: a first structure of the first portion matches a second structure of the second portion; a third structure of the third portion matches a fourth structure of the fourth portion; the first structure mirrors the third structure; and the second structure mirrors the fourth structure.

In some aspects, the techniques described herein relate to a device, wherein a bit width of the lane value corresponds to a number of portions of the PRF.

In some aspects, the techniques described herein relate to a system including: a memory; a processor coupled to the memory and including: a logic circuit; a physical register file (PRF) configured to hold values read from the memory and including: a first portion in a first die layer; and a second portion in a second die layer and at least partially stacked over the first portion; and a control circuit configured to manage access from the logic circuit to the first portion and the second portion with an addressing scheme that uses a lane value to differentiate between the first portion and the second portion.

In some aspects, the techniques described herein relate to a system, wherein a first structure of the first portion matches a second structure of the second portion such that a first path distance of a first data path between the logic circuit and the first portion is similar to a second path distance of a second data path between the logic circuit and the second portion.

In some aspects, the techniques described herein relate to a system, wherein: a first physical location of the first portion has a first address and a first lane value; a second physical location of the second portion has a second address and a second lane value; and the second address is similar to the first address and the second lane value is different from the first lane value such that the second physical location is generally vertically aligned with the first physical location.

In some aspects, the techniques described herein relate to a system, wherein the addressing scheme uses a lane value including 1 bit.

In some aspects, the techniques described herein relate to a system, wherein: the PRF further includes: a third portion lateral to the first portion in the first die layer; and a fourth portion lateral to the second portion in the second die layer and at least partially stacked over the third portion; and the control circuit is further configured to manage access from the logic circuit to the first portion, the second portion, the third portion and the fourth portion with the addressing scheme that uses the lane value to differentiate between the first portion, the second portion, the third portion and the fourth portion.

In some aspects, the techniques described herein relate to a system, wherein: a first structure of the first portion matches a second structure of the second portion; a third structure of the third portion matches a fourth structure of the fourth portion; the first structure mirrors the third structure; and the second structure mirrors the fourth structure.

In some aspects, the techniques described herein relate to a system, wherein a bit width of the lane value corresponds to a number of portions of the PRF.

In some aspects, the techniques described herein relate to a method including: receiving, by a control circuit, an access request for a physical register file (PRF) including a plurality of dies arranged in one or more stacks; and accessing one of the plurality of dies based on a lane value in the access request.

In some aspects, the techniques described herein relate to a method, wherein the access request includes an address corresponding to a physical location with respect to a stack of dies and the lane value identifies a die in the stack of dies.

In some aspects, the techniques described herein relate to a method, wherein accessing the one of the plurality of dies includes accessing multiple physical locations of the one of the plurality of dies.

In some aspects, the techniques described herein relate to a device including: a physical register file (PRF) including: a first portion in a first die layer; and a second portion, in a second die layer, that is at least partially stacked over the first portion; and a control circuit configured to manage access from a logic circuit to the first portion and the second portion.

In some aspects, the techniques described herein relate to a device, wherein a first path distance of a first data path between the logic circuit and the first portion is ostensibly same as a second path distance of a second data path between the logic circuit and the second portion.

In some aspects, the techniques described herein relate to a device, wherein a first structure of the first portion matches a second structure of the second portion.

In some aspects, the techniques described herein relate to a device, wherein the control circuit is configured to manage access to the first portion and the second portion with an addressing scheme that uses a lane value to differentiate between the first portion and the second portion.

In some aspects, the techniques described herein relate to a device, wherein: a first physical location of the first portion has a first address and a first lane value; a second physical location of the second portion has a second address and a second lane value; and the second address is ostensibly same as the first address and the second lane value is different from the first lane value such that the second physical location is generally vertically aligned with the first physical location.

In some aspects, the techniques described herein relate to a device, wherein the first path distance for the first physical location is ostensibly the same as the second path distance for the second physical location.

In some aspects, the techniques described herein relate to a device, wherein the addressing scheme uses a lane value including 1 bit.

In some aspects, the techniques described herein relate to a device, wherein: the PRF further includes: a third portion lateral to the first portion in the first die layer; and a fourth portion, lateral to the second portion in the second die layer, that is at least partially stacked over the third portion; and the control circuit is further configured to manage access from the logic circuit to the first portion, the second portion, the third portion and the fourth portion with an addressing scheme that uses a lane value to differentiate between the first portion, the second portion, the third portion and the fourth portion.

In some aspects, the techniques described herein relate to a device, wherein: a first structure of the first portion matches a second structure of the second portion; a third structure of the third portion matches a fourth structure of the fourth portion; the first structure mirrors the third structure; and the second structure mirrors the fourth structure.

In some aspects, the techniques described herein relate to a device, wherein a bit width of the lane value corresponds to a number of portions of the PRF.

In some aspects, the techniques described herein relate to a system including: a memory; and a processor coupled to the memory and including: a logic circuit; a physical register file (PRF) configured to hold values read from the memory and including: a first portion in a first die layer; and a second portion, in a second die layer, that is at least partially stacked over the first portion; and a control circuit configured to manage access from the logic circuit to the first portion and the second portion with an addressing scheme that uses a lane value to differentiate between the first portion and the second portion.

In some aspects, the techniques described herein relate to a system, wherein a first structure of the first portion matches a second structure of the second portion such that a first path distance of a first data path between the logic circuit and the first portion is ostensibly same as a second path distance of a second data path between the logic circuit and the second portion.

In some aspects, the techniques described herein relate to a system, wherein: a first physical location of the first portion has a first address and a first lane value; a second physical location of the second portion has a second address and a second lane value; and the second address is ostensibly same as the first address and the second lane value is different from the first lane value such that the second physical location is generally vertically aligned with the first physical location.

In some aspects, the techniques described herein relate to a system, wherein the addressing scheme uses a lane value including 1 bit.

In some aspects, the techniques described herein relate to a system, wherein: the PRF further includes: a third portion lateral to the first portion in the first die layer; and a fourth portion, lateral to the second portion in the second die layer, that is at least partially stacked over the third portion; and the control circuit is further configured to manage access from the logic circuit to the first portion, the second portion, the third portion and the fourth portion with the addressing scheme that uses the lane value to differentiate between the first portion, the second portion, the third portion and the fourth portion.

In some aspects, the techniques described herein relate to a system, wherein: a first structure of the first portion matches a second structure of the second portion; a third structure of the third portion matches a fourth structure of the fourth portion; the first structure mirrors the third structure; and the second structure mirrors the fourth structure.

In some aspects, the techniques described herein relate to a system, wherein a bit width of the lane value corresponds to a number of portions of the PRF.

In some aspects, the techniques described herein relate to a method including: receiving, by a control circuit, an access request for a physical register file (PRF) including a plurality of dies arranged in one or more stacks; and accessing one of the plurality of dies based on a lane value in the access request.

In some aspects, the techniques described herein relate to a method, wherein the access request includes an address corresponding to a physical location with respect to a stack of dies and the lane value identifies a die in the stack of dies.

In some aspects, the techniques described herein relate to a method, wherein accessing the one of the plurality of dies includes accessing multiple physical locations of the one of the plurality of dies.

As detailed above, the computing devices and systems described and/or illustrated herein broadly represent any type or form of computing device or system capable of executing computer-readable instructions, such as those contained within the code/firmware/programs described herein. In their most basic configuration, these computing device(s) each include at least one memory device and at least one physical processor.

In some examples, the term “memory device” generally refers to any type or form of volatile or non-volatile storage device or medium capable of storing data and/or computer-readable instructions. In one example, a memory device stores, loads, and/or maintains one or more of the instructions and/or circuits described herein. Examples of memory devices include, without limitation, Random Access Memory (RAM), Read Only Memory (ROM), flash memory, Hard Disk Drives (HDDs), Solid-State Drives (SSDs), optical disk drives, caches, variations, or combinations of one or more of the same, or any other suitable storage memory.

In some examples, the term “physical processor” generally refers to any type or form of hardware-implemented processing unit capable of interpreting and/or executing computer-readable instructions. In one example, a physical processor accesses and/or modifies one or more instructions stored in the above-described memory device. Examples of physical processors include, without limitation, chiplets (e.g., smaller and in some examples more specialized processing units that can coordinate as a single chip), microprocessors, microcontrollers, Central Processing Units (CPUs), Field-Programmable Gate Arrays (FPGAs) that implement softcore processors, Application-Specific Integrated Circuits (ASICs), systems on chip (SoCs), digital signal processors (DSPs), Neural Network Engines (NNEs), accelerators, accelerated processing units (APUs), portions of one or more of the same, variations or combinations of one or more of the same (e.g., a host processor and a co-processor), and/or any other suitable physical processor.

In some examples, the term “physical processor” also refers to and/or includes a co-processor that generally refers to any type or form of hardware-implemented processing unit capable of interpreting and/or executing computer-readable instructions, which in some examples works in conjunction with and/or based on instructions from a host/main processor such as a CPU, and further in some examples accesses and/or modifies one or more instructions stored in the above-described memory device. Examples of co-processors include, without limitation, chiplets, microprocessors, microcontrollers, graphics processing units (GPUs), FPGAs that implement softcore processors, ASICs, SoCs, DSPs, NNEs, accelerators, portions of one or more of the same, variations or combinations of one or more of the same, and/or any other suitable physical processor.

Although described as separate elements/steps, the instructions described and/or illustrated herein can represent portions of a single program or application, including instructions implemented in code, firmware, one or more circuits, etc. In addition, in certain implementations one or more of these instructions can represent one or more software applications or programs that, when executed by a computing device, cause the computing device to perform one or more tasks. For example, one or more of the instructions described and/or illustrated herein represent instructions stored and configured to run on one or more of the computing devices or systems described and/or illustrated herein. In some implementations, one or more instructions can be implemented as a circuit or circuitry, including as part of a firmware, a ROM, one or more logic units, etc. One or more of these instructions can also represent or otherwise be implemented with all or portions of one or more special-purpose computers configured to perform one or more tasks.

In some implementations, the term “computer-readable medium” generally refers to any form of device, carrier, or medium capable of storing or carrying computer-readable instructions. Examples of computer-readable media include, without limitation, transmission-type media, such as carrier waves, and non-transitory-type media, such as magnetic-storage media (e.g., hard disk drives, tape drives, and floppy disks), optical-storage media (e.g., Compact Disks (CDs), Digital Video Disks (DVDs), and BLU-RAY disks), electronic-storage media (e.g., solid-state drives and flash media), and other distribution systems.

The process parameters and sequence of the steps described and/or illustrated herein are given by way of example only and can be varied as desired. For example, while the steps illustrated and/or described herein are shown or discussed in a particular order, these steps do not necessarily need to be performed in the order illustrated or discussed. The various exemplary methods described and/or illustrated herein can also omit one or more of the steps described or illustrated herein or include additional steps in addition to those disclosed.

The preceding description has been provided to enable others skilled in the art to best utilize various aspects of the exemplary implementations disclosed herein. This exemplary description is not intended to be exhaustive or to be limited to any precise form disclosed. Many modifications and variations are possible without departing from the spirit and scope of the present disclosure. The implementations disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of. ” Finally, for ease of use, the terms “including” and “having” (and their derivatives), as used in the specification and claims, are interchangeable with and have the same meaning as the word “comprising.”

What is claimed is:

1. A device comprising:
a physical register file (PRF) comprising:
a first portion in a first die layer; and
a second portion, in a second die layer, that is at least partially stacked over the first portion; and
a control circuit configured to manage access from a logic circuit to the first portion and the second portion.

2. The device of claim 1, wherein a first path distance of a first data path between the logic circuit and the first portion is ostensibly same as a second path distance of a second data path between the logic circuit and the second portion.

3. The device of claim 2, wherein a first structure of the first portion matches a second structure of the second portion.

4. The device of claim 3, wherein the control circuit is configured to manage access to the first portion and the second portion with an addressing scheme that uses a lane value to differentiate between the first portion and the second portion.

5. The device of claim 4, wherein:
a first physical location of the first portion has a first address and a first lane value;
a second physical location of the second portion has a second address and a second lane value; and
the second address is ostensibly same as the first address and the second lane value is different from the first lane value such that the second physical location is generally vertically aligned with the first physical location.

6. The device of claim 5, wherein the first path distance for the first physical location is ostensibly the same as the second path distance for the second physical location.

7. The device of claim 4, wherein the addressing scheme uses a lane value comprising 1 bit.

8. The device of claim 1, wherein:
the PRF further comprises:
a third portion lateral to the first portion in the first die layer; and
a fourth portion, lateral to the second portion in the second die layer, that is at least partially stacked over the third portion; and
the control circuit is further configured to manage access from the logic circuit to the first portion, the second portion, the third portion and the fourth portion with an addressing scheme that uses a lane value to differentiate between the first portion, the second portion, the third portion and the fourth portion.

9. The device of claim 8, wherein:
a first structure of the first portion matches a second structure of the second portion;
a third structure of the third portion matches a fourth structure of the fourth portion;
the first structure mirrors the third structure; and
the second structure mirrors the fourth structure.

10. The device of claim 9, wherein a bit width of the lane value corresponds to a number of portions of the PRF.

11. A system comprising:
a memory; and
a processor coupled to the memory and comprising:
a logic circuit;
a physical register file (PRF) configured to hold values read from the memory and comprising:
a first portion in a first die layer; and
a second portion, in a second die layer, that is at least partially stacked over the first portion; and
a control circuit configured to manage access from the logic circuit to the first portion and the second portion with an addressing scheme that uses a lane value to differentiate between the first portion and the second portion.

12. The system of claim 11, wherein a first structure of the first portion matches a second structure of the second portion such that a first path distance of a first data path between the logic circuit and the first portion is ostensibly same as a second path distance of a second data path between the logic circuit and the second portion.

13. The system of claim 12, wherein:
a first physical location of the first portion has a first address and a first lane value;
a second physical location of the second portion has a second address and a second lane value; and
the second address is ostensibly same as the first address and the second lane value is different from the first lane value such that the second physical location is generally vertically aligned with the first physical location.

14. The system of claim 13, wherein the addressing scheme uses a lane value comprising 1 bit.

15. The system of claim 11, wherein:
the PRF further comprises:
a third portion lateral to the first portion in the first die layer; and
a fourth portion, lateral to the second portion in the second die layer, that is at least partially stacked over the third portion; and
the control circuit is further configured to manage access from the logic circuit to the first portion, the second portion, the third portion and the fourth portion with the addressing scheme that uses the lane value to differentiate between the first portion, the second portion, the third portion and the fourth portion.

16. The system of claim 15, wherein:
a first structure of the first portion matches a second structure of the second portion;
a third structure of the third portion matches a fourth structure of the fourth portion;
the first structure mirrors the third structure; and
the second structure mirrors the fourth structure.

17. The system of claim 16, wherein a bit width of the lane value corresponds to a number of portions of the PRF.

18. A method comprising:
receiving, by a control circuit, an access request for a physical register file (PRF) comprising a plurality of dies arranged in one or more stacks; and
accessing one of the plurality of dies based on a lane value in the access request.

19. The method of claim 18, wherein the access request includes an address corresponding to a physical location with respect to a stack of dies and the lane value identifies a die in the stack of dies.

20. The method of claim 18, wherein accessing the one of the plurality of dies includes accessing multiple physical locations of the one of the plurality of dies.
